(19) United States
(12) Patent Application Publication
(10) Pub. No.: US 2015/0225844 A1
(43) Pub. Date: Aug. 13, 2015

(54) THIN GRAPHENE FILM FORMATION

(71) Applicant: Universiteit Leiden, Leiden (NL)

(72) Inventors: Dirk Van Baarle, Leiden (NL); Richard Van Rijn, Den Haag (NL)

(73) Assignee: Universiteit Leiden, Leiden (NL)

(21) Appl. No.: 14/424,638

(22) PCT Filed: Aug. 30, 2013
(86) PCT No.: PCT/EP2013/068033

§ 371 Date: Feb. 27, 2015

Related U.S. Application Data
(60) Provisional application No. 61/695,522, filed on Aug. 31, 2012.

(30) Foreign Application Priority Data
Aug. 31, 2012 (GB) 1215579.2

(51) Int. Cl. C23C 16/26; C23C 16/46; C23C 16/52; C23C 16/458

(52) U.S. Cl. CPC C23C 16/26; C23C 16/458; C23C 16/46; C23C 16/52

(57) ABSTRACT

A method of forming a graphene film on one or more surfaces of a metal substrate, the method comprising the steps of: (i) heating a metal substrate defining one or more surfaces to an exposure temperature; (ii) restricting the metal flux from the one or more surfaces at the exposure temperature by provision of one or more counter surfaces proximal to one or more of the surfaces of the substrate; (iii) exposing the substrate to a carbon containing precursor gas at the exposure temperature so as to form a graphene film on the or each surface of the substrate.

The invention relates to a method of forming a graphene film on one or more surfaces of a substrate.

Graphene has specific properties that render it compatible with a wide range of applications such as fast and flexible electronics, lasers, bio-sensors, atomically thin protective coatings, hydrogen storage and energy storage. In particular, graphene demonstrates higher carrier mobility than conventional semiconductor materials, which can be exploited to improve the speed of electronics including microprocessors.

Chemical vapour deposition (CVD) has conventionally been used to make graphene. In such methods, a surface of a metal substrate is exposed to a carbon-containing precursor gas, such as ethylene or benzene, which results in adsorption of precursor gas molecules on the surface of the metal substrate. The adsorbed precursor gas molecules then decompose to form carbon, which remain on the surface of the metal substrate to form graphene. Any volatile components are typically pumped away by a vacuum pumping system.

Certain methods of making graphene film using CVD involve the use of a metal substrate formed from metals such as nickel or copper. This is at least in part because both nickel and copper have a similar lattice structure to that of graphene.

However, as CVD is performed at high temperature and low pressure, it is known for metal atoms to evaporate or sublime from the surface of the substrate. This leads to an uneven substrate surface which in turn provides for wrinkled or incomplete formation of graphene on that surface. This can provide particular challenges when seeking to produce a large area of continuous graphene.

Such methods may also provide graphene layers with small grain sizes, which can be detrimental to carrier mobility, for example because the crystal lattices of adjacent grains typically do not align. Small grain sizes may result from, for example, a high and/or non-uniform nucleation density at formation or poor crystal alignment at formation or a combination thereof.

There is therefore a need for a method for producing such a large area of continuous graphene, as well as for a method for producing graphenes of reliable and/or substantially predictable surface relief, a relatively low and/or uniform nucleation density and well aligned lattices.

According to one aspect of the invention, there is provided a method of forming a graphene film on one or more surfaces of a metal substrate, the method comprising the steps of:
(i) heating a metal substrate defining one or more surfaces to an exposure temperature;
(ii) restricting the metal flux from the one or more surfaces at the exposure temperature by provision of one or more counter surfaces proximal to one or more of the surfaces of the substrate;
(iii) exposing the substrate to a carbon containing precursor gas at the exposure temperature so as to form a graphene film on the or each surface of the substrate.

The inventors have found that in providing a counter surface close to the substrate, the topography of the graphene formed on the substrate surface can be controlled. It is believed that surface metal atoms that have evaporated or sublimed from the surface of the substrate are restricted from escaping the region of the surface and accordingly the metal flux from the surface is reduced, allowing for a more consistent substrate surface on which the graphene layer can grow.

In embodiments of the invention, the method may include the step of restricting the metal flux from the one or more surfaces at the exposure temperature by provision of one or more counter surfaces proximal to one or more of the surfaces of the substrate to restrict surface metal atoms that have evaporated or sublimed from the one or more surfaces of the substrate from escaping the region of the one or more surfaces.

The temperature of the one or more counter surfaces may be controlled to provide a temperature differential between the substrate and the counter surface. The provision of a temperature differential between the substrate and the counter surface may allow control over the metal flux from the one or more surfaces of the metal substrate at the exposure temperature.

Preferably, the carbon containing precursor gas is not formed from counter surface, for example by thermal degradation, evaporation or sublimation from the counter surface.

Preferably, the carbon containing precursor gas comprises one or more carbon containing compounds, for example alkanes, alkenes or aryl compounds. Preferably the carbon contain compounds are present at a partial pressure of 10⁻⁴ mbar to 10⁻² mbar.

Preferably, the carbon containing precursor gas additionally comprises hydrogen. Preferably the hydrogen in present in the carbon containing precursor gas is present at a partial pressure of 10⁻⁴ mbar to 10⁻² mbar, e.g. 10⁻⁴ mbar to 10⁻³ mbar.

In preferred embodiments, the one or more counter surfaces are held at a higher or lower temperature than the substrate. Without wishing to be bound by any particular theory, it is believed that ensuring that the counter surface is at a higher temperature than the substrate prevents gaseous metal ions from forming a film on the counter surface, in turn preventing a large metal atom flux from the surface of the substrate.

Preferably, the one or more counter surfaces are held at a temperature of up to 500° C. higher than the exposure temperature of the metal substrate. In preferred embodiments, the one or more counter surfaces is held at a temperature of up to 400° C. higher, for example up to 300° C. higher, up to 200° C. higher or up to 100° C. higher, than the exposure temperature of the metal substrate. However, in some embodiments the temperature of the counter surface may be substantially equal to the exposure temperature. It will be appreciated that the temperature of the counter surface being substantially equal to the exposure temperature includes the temperature of the counter surface being exactly equal to the exposure temperature, i.e. a zero temperature differential between the temperature of the counter surface and the exposure temperature.

Preferably, the exposure temperature is in the range 500° C. to 2000° C. In preferred embodiments, the exposure temperature is in the range 600° C. to 1800° C., for example in the range 600° C. to 1500° C., 700° C. to 1200° C., 800° C. to 1000° C. or 900° C. to 1100° C.

Of course, the skilled person understands that the exposure temperature and the temperature of the counter surface may be selected to ensure optimal performance with reference the particular materials which comprise the counter surface and/or the metal substrate.

The one or more counter surfaces are preferably heated by direct contact with or by radiated heat from a heat source. The metal substrate may be at least partially heated to the exposure temperature by radiated heat from the one or more counter surfaces. In other embodiments, the metal substrate may be at least partially heated to the exposure temperature by direct contact with or by radiated heat from another heat source. Indeed, in some embodiments, the metal substrate may be subjected to no direct heat.

Preferably, the metal substrate is an elemental metal substrate, for example a copper or nickel substrate.

Preferably, the one or more counter surfaces comprise a material different to the metal substrate. For example, the one or more counter surfaces may comprise a material, such as a metal, having a higher vapour pressure and/or boiling point and/or sublimation point than the metal substrate. In some embodiments, the counter surface may comprise molybdenum, e.g. metallic molybdenum. Preferably, the one or more counter surfaces may comprise a ceramic or mineral material. Sapphire represents a preferred example of such a material. Alternative materials include e.g. boron nitride.

In some embodiments, the one or more counter surfaces may comprise the same material as the metal substrate. In such circumstances, the one or more counter surfaces may be held at substantially the exposure temperature of the metal substrate or at a temperature higher or lower than the exposure temperature of the metal substrate.

In some embodiments, at least part of the metal substrate may be in intimate contact with the one or more counter surfaces. Alternatively, the metal substrate may be spaced from the counter surface by a distance of less than or equal to 100 mm, for example less than or equal to 50 mm or less than or equal to 25 mm. In preferred embodiments, the metal substrate is spaced from the one or more counter surfaces by less than or equal to 10 mm, less than or equal to 5 mm or less than or equal to 1 mm. In most preferred embodiments, the metal substrate is spaced from the one or more counter surfaces by less than or equal to 750 μm, for example less than or equal to 500 μm, less than or equal to 250 μm, less than or equal to 100 μm or less than or equal to 50 μm.

In certain embodiments, the metal substrate may be separated from the one or more counter surfaces by one or more spacers. Optionally, the spacer or spacers may be arranged to further reduce or prevent the escape of gaseous metal atoms from a region between the substrate and the one or more counter surfaces, for example by partially or completely surrounding that region.

Preferably, at least one of the one or more surfaces of the metal substrate is arranged in a substantially parallel plane to at least one of the one or more counter surfaces.

Preferably, the exposure of the substrate to the carbon containing precursor gas takes place at a pressure of less than 100 mbar. More preferably, the exposure of the substrate to the carbon containing precursor gas takes place at a pressure of less than or equal to 50 mbar, for example less than or equal to 25 mbar, less than or equal to 10 mbar, less than or equal to 1 mbar or less than or equal to 0.1 mbar.

More preferably, the exposure of the substrate to the carbon containing precursor gas takes place at a pressure of less than or equal to 10⁻² mbar, for example less than 5×10⁻³ mbar or less than 10⁻³ mbar.

In some embodiments, the step of exposing the substrate to a carbon containing precursor gas may be performed so as to dissolve carbon atoms into the substrate and saturate the substrate with carbon atoms and is followed by cooling the substrate so as to segregate the dissolved carbon atoms from the substrate to form a graphene film on the or each surface of the substrate. In such circumstances, the method preferably further includes selecting the substrate on the basis of its thickness to control the depth of the graphene film formed on the or each surface of the substrate on cooling the substrate so as to segregate the dissolved carbon atoms from the substrate.

In some embodiments, the metal substrate may be supported on a substrate support member. The substrate support member preferably comprises a material, such as a metal, having a higher vapour pressure and/or boiling point and/or sublimation point than the metal substrate. In some embodiments, the substrate support member may comprise molybdenum, e.g. metallic or elemental molybdenum. Preferably, the substrate support member may comprise a ceramic or mineral material. Sapphire represents a preferred example of such a material.

In some embodiments, the metal substrate may be at least partially spaced from the substrate support member, for example by the provision of one or more spacers.

Preferably, the method includes a preliminary step of annealing the metal substrate at low pressure and elevated temperature, for example in the presence of hydrogen.

In certain embodiments, the method may comprise preliminary steps of:
(a) disposing the or a substrate support member having a substrate support surface adjacent to a metal substrate precursor;
(b) heating the metal substrate precursor to an evaporation temperature at reduced pressure so as to deposit a metal substrate layer on the substrate support surface.

This method of depositing a new metal film onto the substrate support surface provides a copper film with extremely high purity. This minimises or eliminates the effects of randomly distributed contaminations that may be found within a metal foil, thereby providing a graphene foil having a highly uniform nucleation density.

Preferably, the substrate support surface is held at a lower temperature than the evaporation temperature of the metal substrate precursor.

In some embodiments, the metal substrate precursor may subsequently at least partially form the counter surface.

The method may include the step of providing a heater source in intimate contact with the one or more counter surfaces.

The method may further include the preliminary step of heating the metal substrate to an evaporation temperature at reduced pressure so as to create a negative or positive net metal flux at the one or more surfaces of the metal substrate.

According to another aspect of the invention, there is provided an arrangement for forming a graphene film on one or more surfaces of a metal substrate, the arrangement comprising:
a. a metal substrate defining one or more surfaces;
b. a heat source to heat the metal substrate to an exposure temperature;
c. one or more counter surfaces provided proximal to one or more of the surfaces of the substrate to restrict the metal flux from the one or more surfaces at the exposure temperature;
d. a carbon containing precursor gas source to expose the substrate to a carbon containing precursor gas at the exposure temperature so as to form a graphene film on the or each surface of the substrate.

In embodiments of the invention, the arrangement may include one or more counter surfaces provided proximal to one or more of the surfaces of the substrate to restrict surface metal atoms that have evaporated or sublimed from the one or more surfaces of the substrate from escaping the region of the one or more surfaces to restrict the metal flux from the one or more surfaces at the exposure temperature.

The one or more counter surfaces may be arranged to be heated by direct contact with or by radiated heat from the heat source. In some embodiments, the metal substrate may be arranged to be at least partially heated to the exposure temperature by radiated heat from the one or more counter surfaces. In other embodiments, the arrangement may include another heat source, wherein the metal substrate may be arranged to be at least partially heated to the exposure temperature by direct contact with or by radiated heat from the another heat source.

The arrangement may include a pressure controller to create a reduced pressure, wherein the exposure of the substrate to the carbon containing precursor gas may take place at the reduced pressure, for example a pressure of less than 100 mbar.

Preferably, the carbon containing precursor gas source is configured to expose the substrate to a carbon containing precursor gas so as to dissolve carbon atoms into the substrate and saturate the substrate with carbon atoms and thereby enable, upon cooling of the substrate, segregation of the dissolved carbon atoms from the substrate to form a graphene film on the or each surface of the substrate. In some embodiments, the metal substrate may be selected on the basis of its thickness to control the depth of the graphene film formed on the or each surface of the substrate on cooling the substrate so as to segregate the dissolved carbon atoms from the substrate.

The arrangement may include:
a. a metal substrate precursor, the or a substrate support member having a substrate support surface being disposed adjacent to the metal substrate precursor;
b. a heat source;
c. a pressure controller to create a reduced pressure;
wherein the heat source and pressure controller may be configured to enable heating of the metal substrate precursor to an evaporation temperature at reduced pressure so as to deposit a metal substrate layer on the substrate support surface.

The heater source may be provided in intimate contact with the one or more counter surfaces.

Preferably, the arrangement is held within a vacuum chamber, preferably a ultra high vacuum chamber.

The arrangement may include a pressure controller to create a reduced pressure, wherein the heat source and pressure controller are configured to enable heating of the metal substrate to an evaporation temperature at reduced pressure so as to create a negative or positive net metal flux at the one or more surfaces of the metal substrate.

Embodiments of the present invention will now be described by way of example only and with reference to the following drawings:

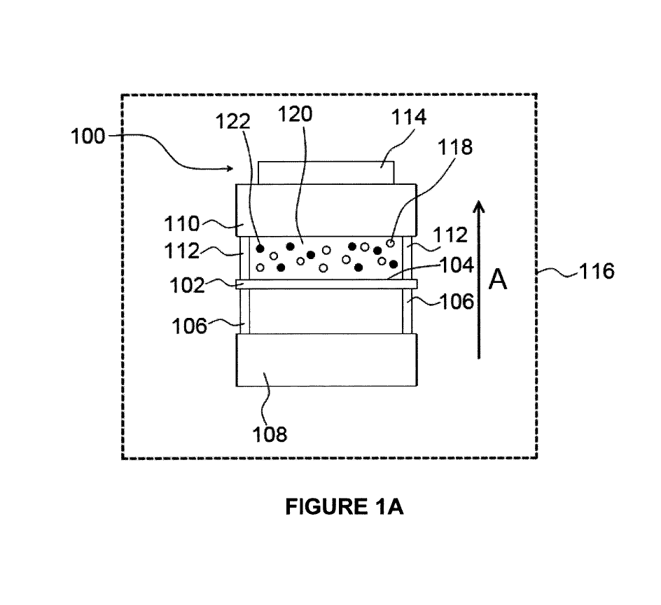

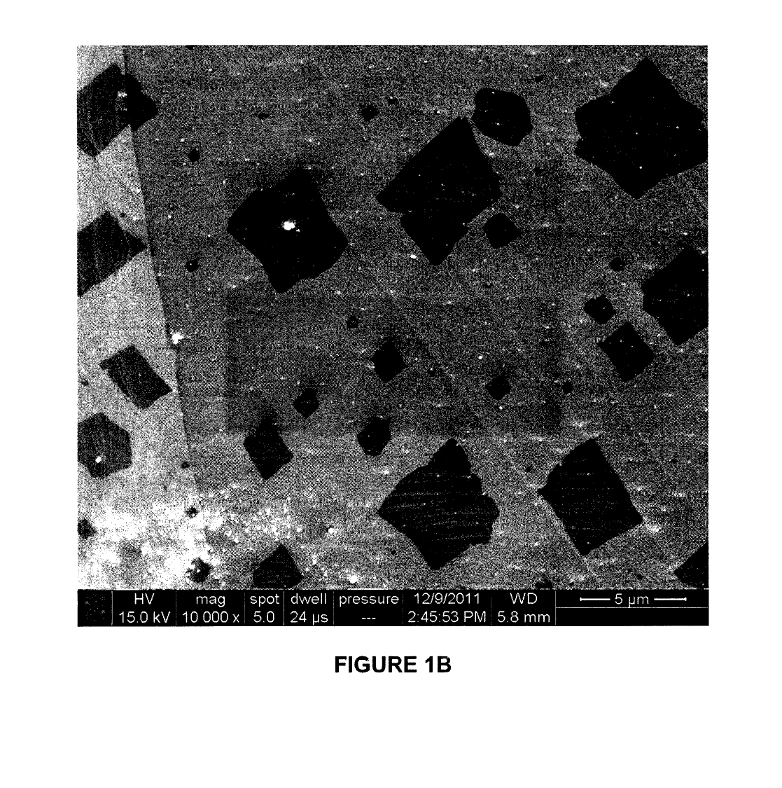

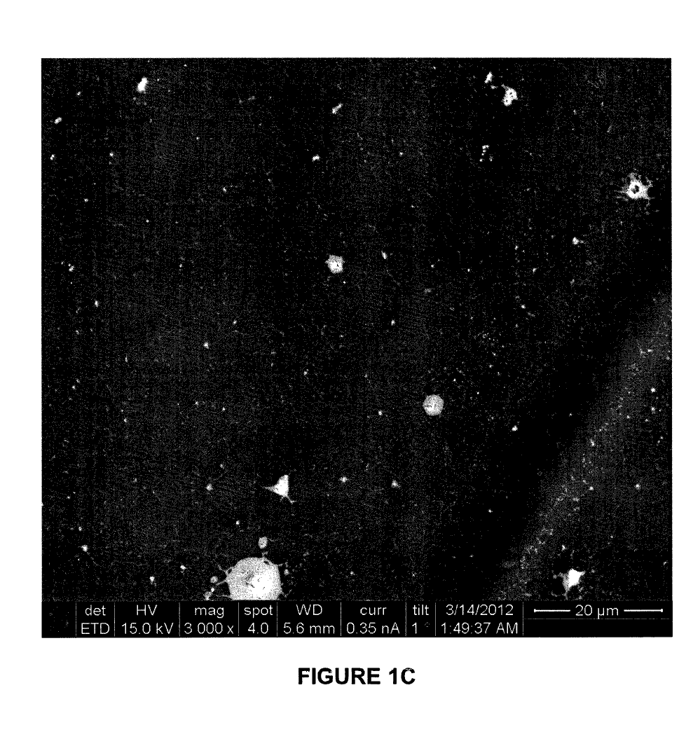

FIG. 1A shows an arrangement for performing a method according to the invention;

FIG. 1B shows an SEM photograph of a graphene layer grown by a method according to the invention;

FIG. 1C shows an SEM photograph of a graphene layer grown by a method according to the invention;

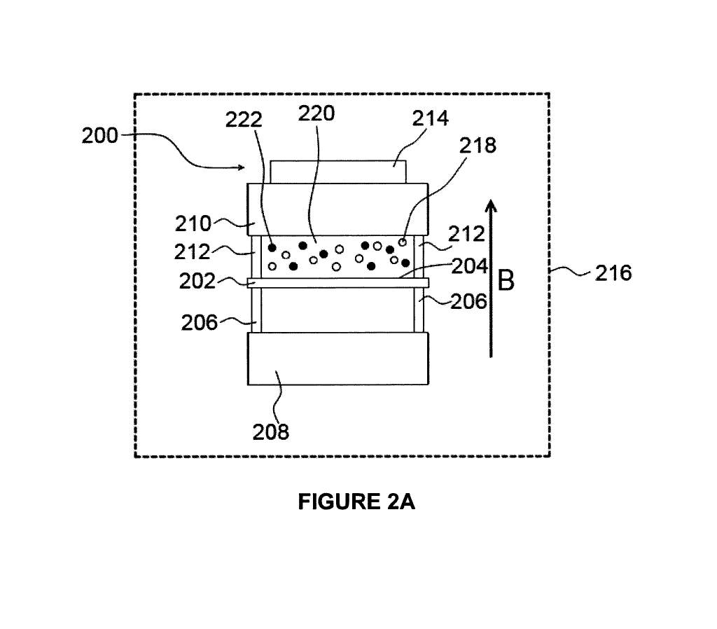

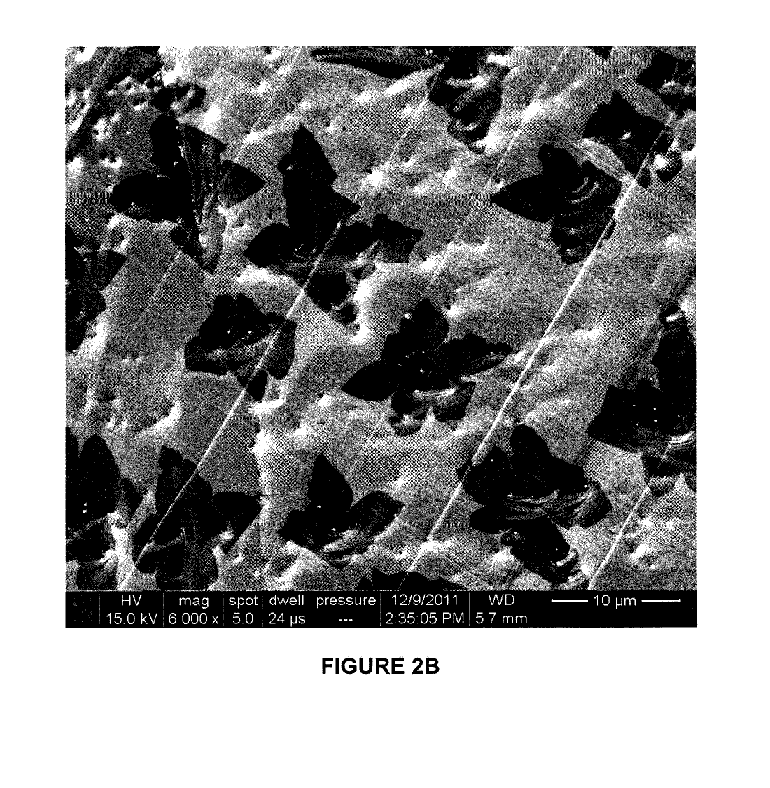

FIG. 2A shows an arrangement for performing a method according to the invention;

FIG. 2B shows an SEM photograph of a graphene layer grown by a method according to the invention;

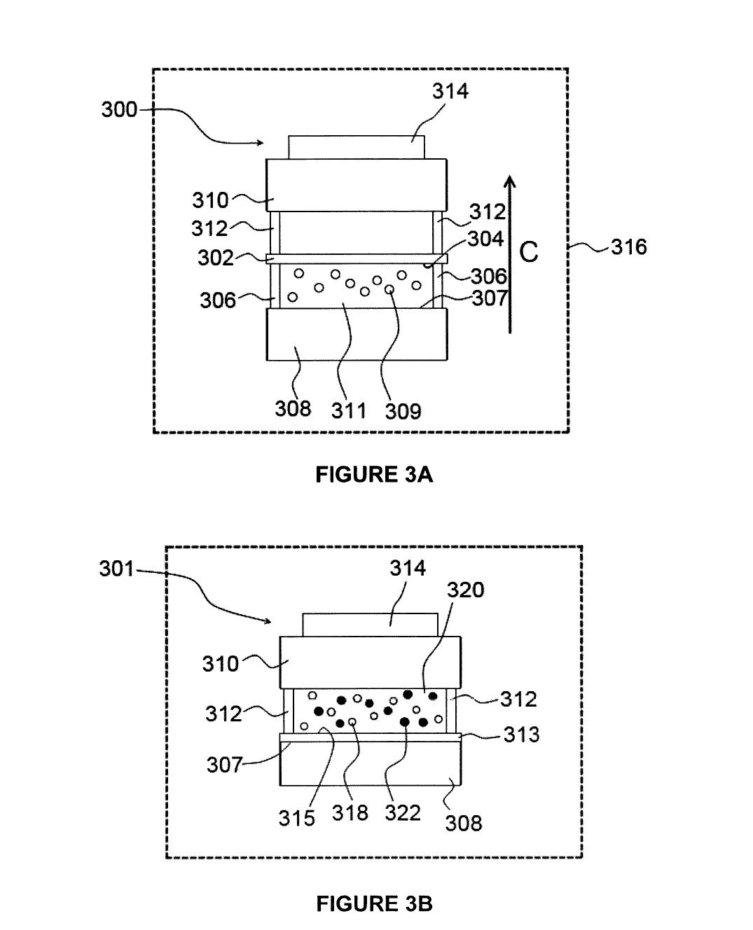

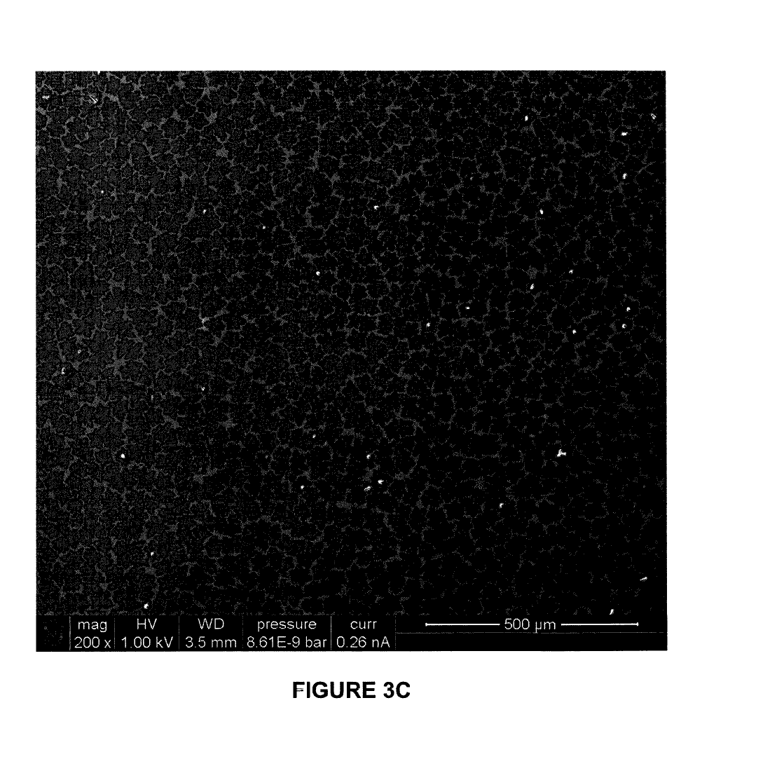

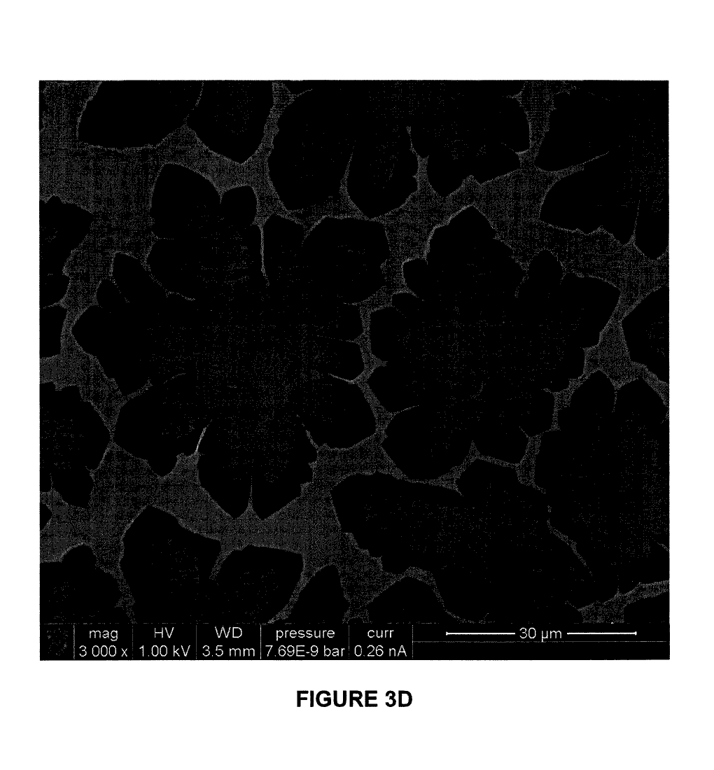

FIG. 3A shows an arrangement for performing a part of a method according to the invention;

FIG. 3B shows an arrangement for performing a method according to the invention;

FIG. 3C shows an SEM photograph of a graphene layer grown by a method according to the invention;

FIG. 3D shows an SEM photograph of a graphene layer grown by a method according to the invention;

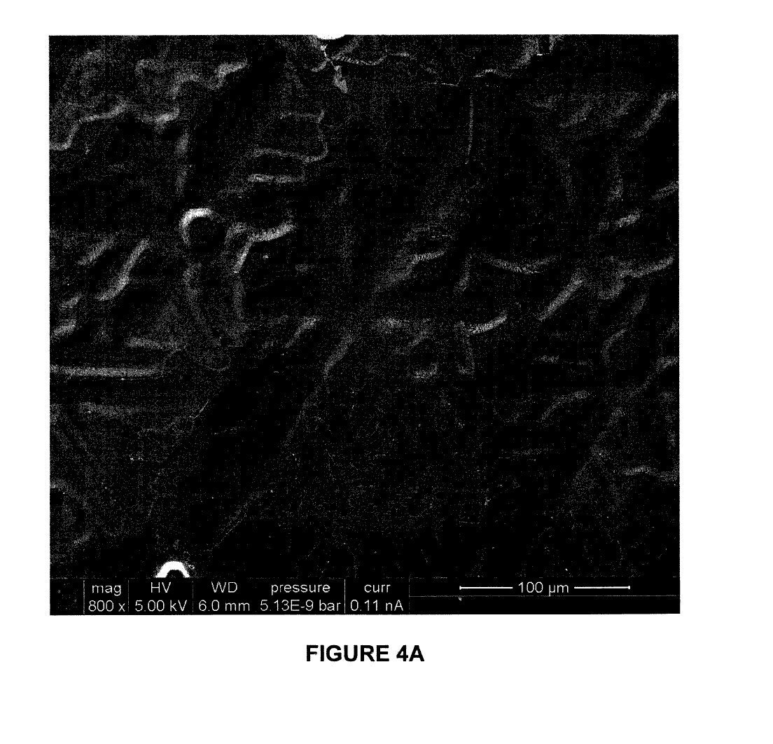

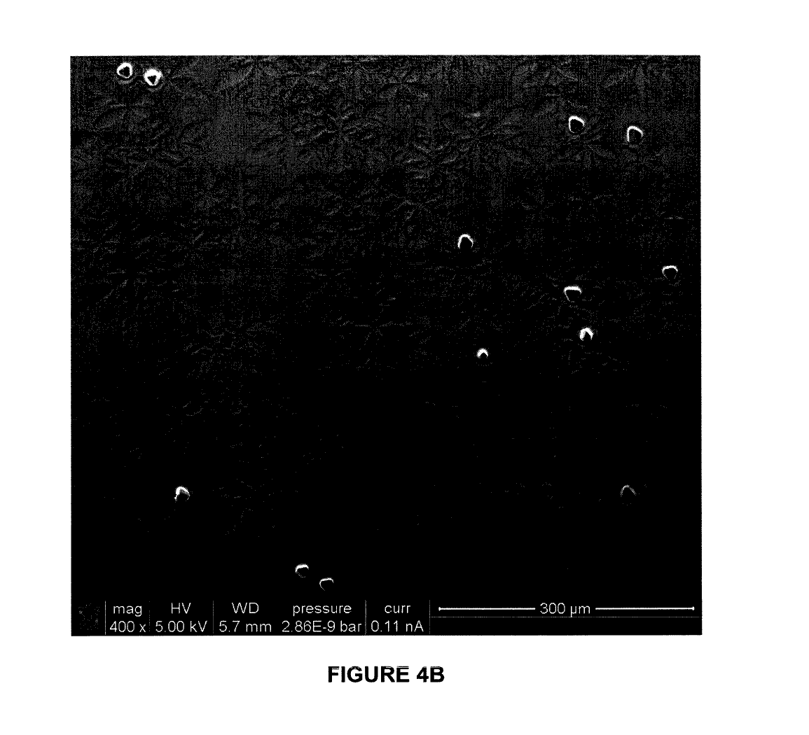

FIG. 4A shows an SEM photograph of a graphene layer grown by a method according to the invention;

FIG. 4B shows an SEM photograph of a graphene layer grown by a method according to the invention;

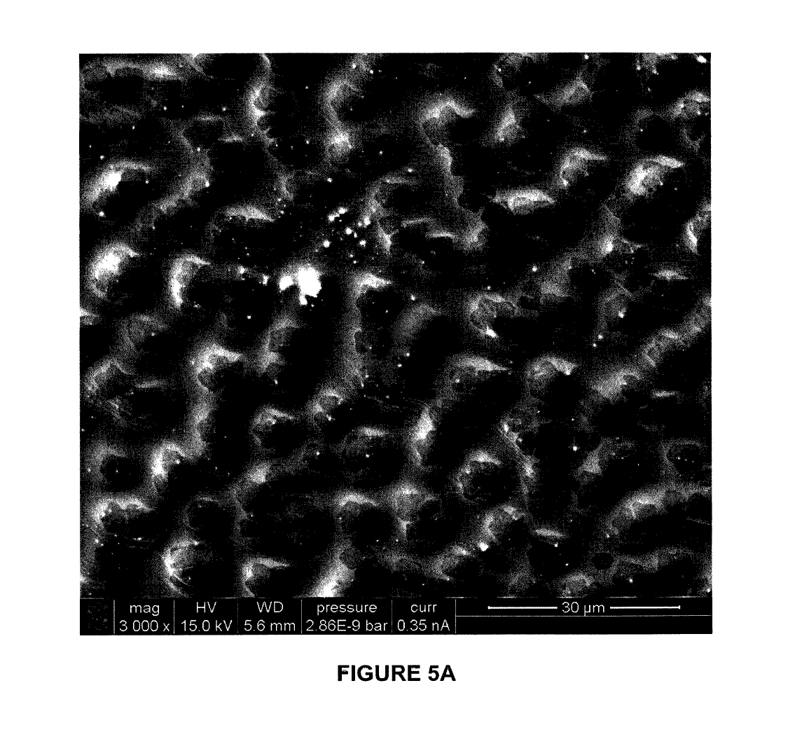

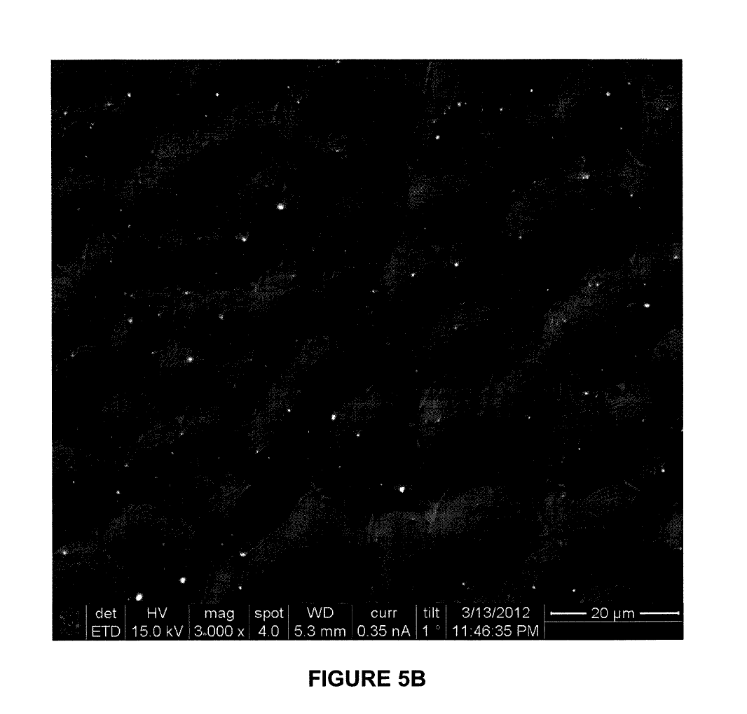

FIGS. 5A and 5B show SEM photographs of a graphene layer grown by a method according to the prior art;

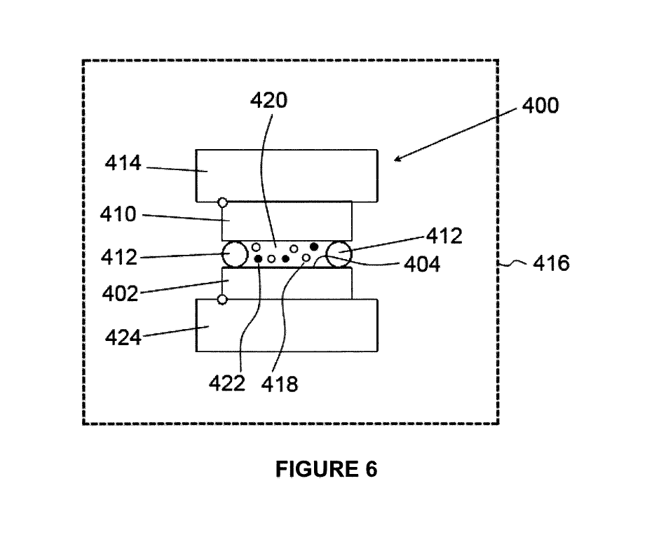

FIG. 6 shows an arrangement for performing a method according to the invention;

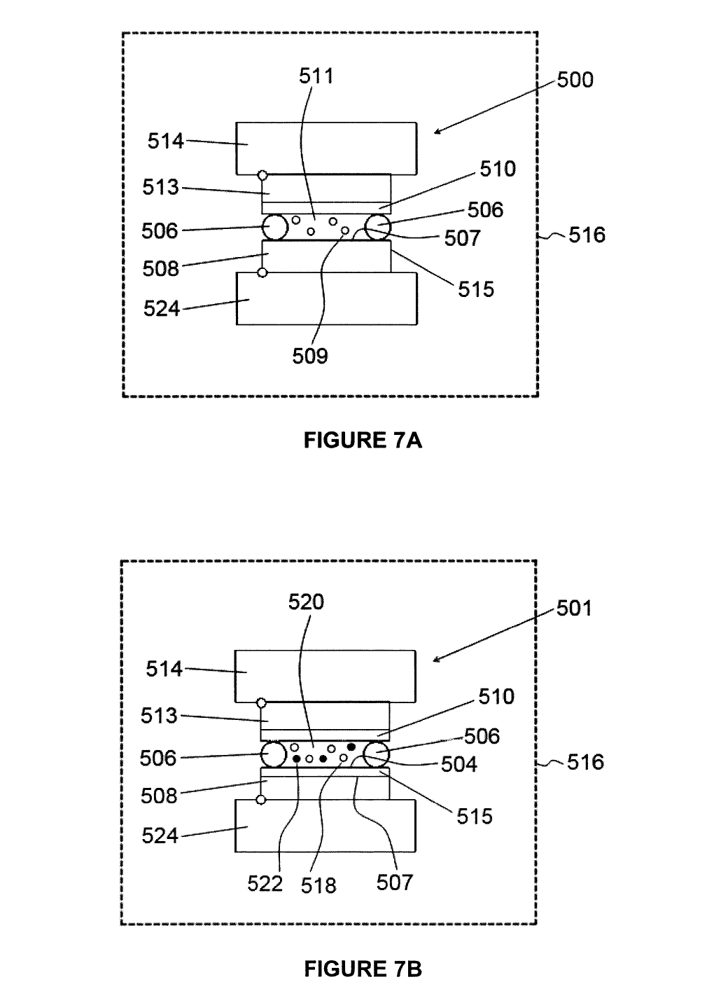

FIGS. 7A and 7B shows an arrangement for performing a method according to the invention;

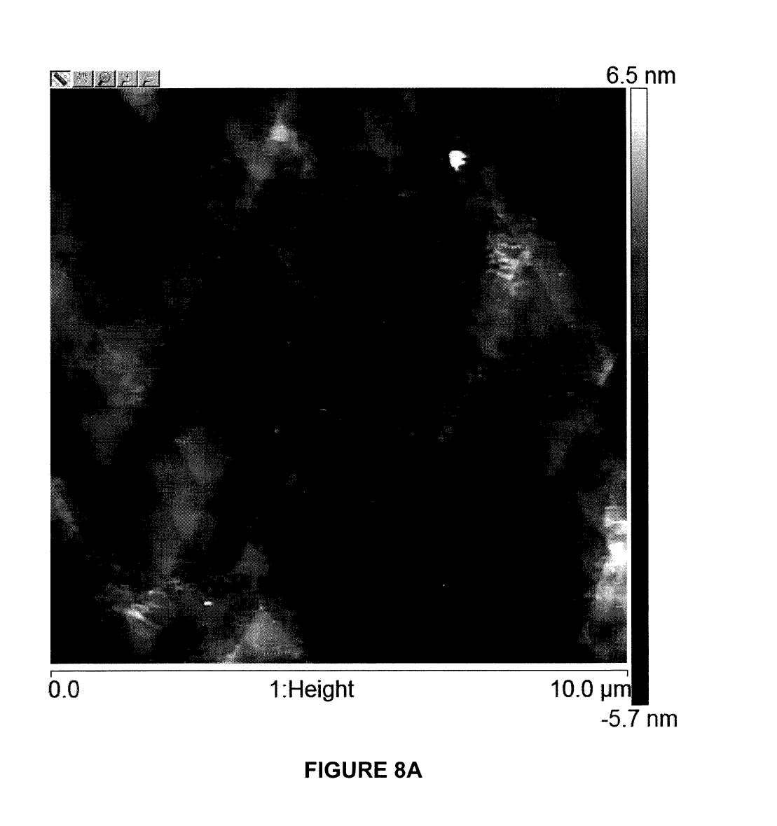

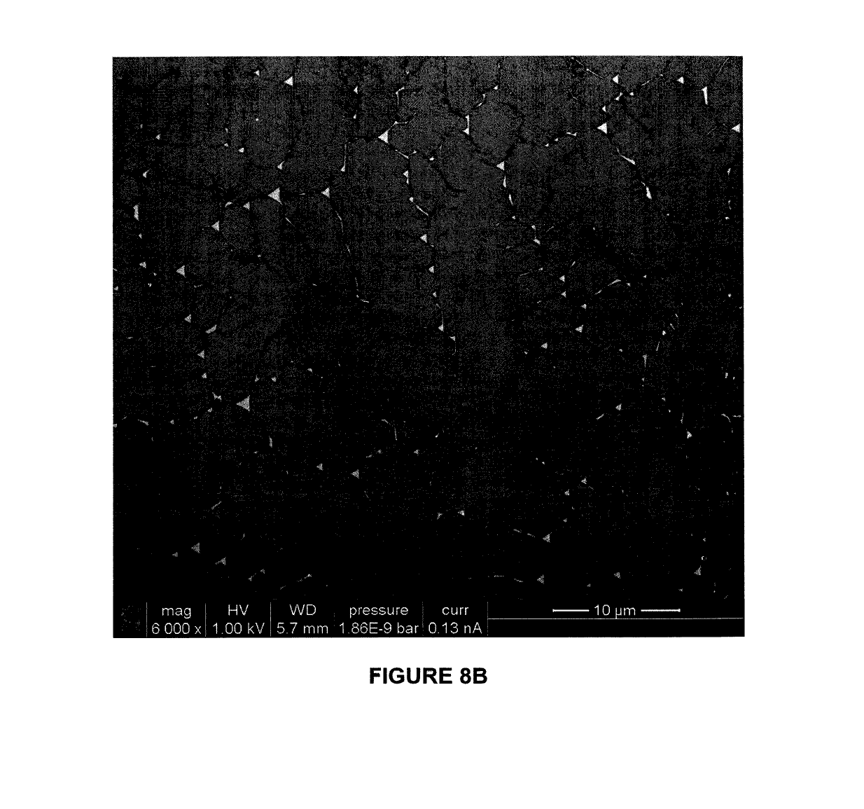

FIGS. 8A and 8B respectively show AFM and SEM photographs of a graphene layer grown by a method according to the invention.

An arrangement 100 for performing a method in accordance with an embodiment of the invention is shown in FIG. 1A.

The arrangement 100 includes a copper substrate 102 having a growth surface 104 on which it is intended to grow a layer of graphene. The copper substrate 102 is mounted by way of spacers 106 on a sapphire substrate support member 108.

Facing the growth surface 104 of the copper substrate 102 and in a substantially parallel plane thereto is positioned a sapphire counter surface 110. Spacers 112 are provided between the sapphire counter surface 110 and the growth surface 104 of the copper substrate 102 in order to maintain a distance of 250 μm therebetween.

A heater 114 is provided in intimate contact with the sapphire counter surface 110. The entire arrangement 100 is held within an ultra high vacuum chamber 116.

In use, the pressure in the ultra high vacuum chamber 116 is reduced to less than around 10⁻⁵ mbar and the sapphire counter surface 110 is slowly heated to around 1050° C. This in turn heats the copper substrate 102 by radiated heat to around 950° C., close to the melting point of copper (1085° C.). The temperature of the sapphire substrate support 108 is cooler still, the temperature of the elements within the vacuum chamber increasing in the direction A. Hydrogen (at a partial pressure of about 7×10⁻⁵ mbar) is added to clean and/or anneal the copper substrate 102 during the heating. The arrangement 100 is held at the high temperature for 2 hours.

Where copper evaporates from the growth surface 104 to produce gaseous copper 118, that gaseous copper 118 is restricted in its movement to the volume within the small interstitial space 120 between the growth surface 104 and the counter surface 110. This effect is enhanced where the spacers 112 also fully or partially prevent escape of gaseous copper from the interstitial space 120.

Moreover, as the counter surface 110 is held at a higher temperature than the copper substrate 102, the gaseous copper 118 does not condense and/or form a copper film on the counter surface 110. The effect is that the gaseous copper 118 preferentially condenses on the growth surface 104, in turn providing a copper atom flux at the growth surface 104 of zero or near zero and ensuring that the surface is substantially flat over its entire area.

While the temperature of the counter surface 110 and the copper substrate 102 is maintained, ethylene gas 122 is introduced to the interstitial space 120 between the growth surface and the counter surface 110 at a partial pressure of 2×10⁻³ mbar. Hydrogen gas is present at this stage at a partial pressure of 6×10⁻⁴ mbar. The substrate 102 was exposed to the ethylene gas for 30 mins.

Without wishing to be bound by a particular theory, it is understood that the copper present acts as a catalyst for the decomposition of ethylene. When the concentration of carbon resulting from this decomposition reaches a critical level, nuclei of carbon form on the growth surface 104 of the copper substrate 102, around which graphene is formed. A uniform layer of graphene is thus formed on the growth surface 104.

### Example 1A

A 1 cm² graphene layer was produced according to the method described in relation to FIG. 1, above. In this Example, graphene growth was halted before completion. An SEM photograph (10000× magnification) showing graphene formed on the growth surface 104 is shown in FIG. 1B. As can be seen, the graphene regions (shown as dark regions) are flat and uniform and of high quality.

### Example 1B

A 1 cm² graphene layer was produced according to the method described in relation to FIG. 1, above. An SEM photograph (3000× magnification) showing graphene formed on the growth surface 104 is shown in FIG. 1C. As can be seen, the graphene layer is flat and uniform and of high quality, with few regions of exposed copper (shown as bright spots).

Another arrangement 200 for performing a method in accordance with an embodiment of the invention is shown in FIG. 2A.

The arrangement 200 includes a copper substrate 202 having a growth surface 204 on which it is intended to grow a layer of graphene. The copper substrate 202 is mounted by way of spacers 206 on a sapphire substrate support member 208.

Facing the growth surface 204 of the copper substrate 202 and in a substantially parallel plane thereto is positioned a copper counter surface 210. Spacers 212 are provided between the copper counter surface 210 and the growth surface 204 of the copper substrate 202 in order to maintain a distance of 250 μm therebetween.

A heater 214 is provided in intimate contact with the copper counter surface 210. The entire arrangement 200 is held within an ultra high vacuum chamber 216.

In use, the pressure in the ultra high vacuum chamber 116 is reduced to less than around 1×10⁻⁵ mbar and the counter surface 210 is slowly heated to around 1050° C. This in turn heats the copper substrate 202 by radiated heat to around 950° C. The temperature of the sapphire substrate support 208 is cooler still, the temperature of the elements within the vacuum chamber increasing in the direction B. Hydrogen (at a partial pressure of about 7×10⁻⁵ mbar) is added to clean and/or anneal the copper substrate 202 during the heating. The arrangement 200 is held at the high temperature for 2 hours.

Where copper evaporates from the growth surface 204 to produce gaseous copper 218, that gaseous copper 218 is restricted in its movement to the volume within the small interstitial space 220 between the growth surface 204 and the counter surface 210. This effect is enhanced where the spacers 212 also fully or partially prevent escape of gaseous copper from the interstitial space 220.

Moreover, as the counter surface 210 is held at a higher temperature than the copper substrate 202, copper also undergoes evaporation from that counter surface 210. The gaseous copper 218 produced from the counter surface 210 and the growth surface 204 does not condense and/or form a copper film on the counter surface 210. Instead, the effect is that the gaseous copper 218 preferentially condenses on the growth surface 204, in turn providing a positive copper atom flux at the growth surface 204.

While the temperature of the counter surface 210 and the copper substrate 202 is maintained, a carbon containing precursor gas 222 is introduced to the interstitial space 120 between the growth surface and the counter surface 210 at a partial pressure of 2×10⁻³ mbar. Hydrogen gas is also present at a partial pressure of 6×10⁻⁴ mbar. A layer of graphene is thus formed on the growth surface 204.

This method is of particular advantage where it is desired to at least partially reduce the impact of impurities in the copper substrate 202, as the deposition of fresh copper on the growth surface 204 provides a pure and effective template for the growth of graphene.

### Example 2

A 1 cm² graphene layer was produced according to the method described in relation to FIG. 2, above. In this Example, graphene growth was halted before completion (after 15 minutes of ethylene exposure). An SEM photograph showing graphene formed on the growth surface 204 is shown in FIG. 2B. As can be seen, the graphene layer appears to be formed in valleys on the growth surface 204 in a uniform nucleation pattern.

A further arrangement 300 for performing a method in accordance with an embodiment of the invention is shown in FIGS. 3A and 3B.

The arrangement 300 includes a copper substrate 302 having an evaporation surface 304 from which it is intended to evaporate copper. The copper substrate 302 is mounted by way of spacers 306 on a sapphire substrate support member 308 such that the evaporation surface 304 is opposed to a substrate support surface 307 of the substrate support member 308.

On an opposing side of the copper substrate 302 is positioned a sapphire counter surface 310. Spacers 312 are provided between the sapphire counter surface 310 and the copper substrate 302 in order to maintain a space therebetween.

A heater 314 is provided in intimate contact with the sapphire counter surface 310. The entire arrangement 300 is held within an ultra high vacuum chamber 316.

Initially, the pressure in the high vacuum chamber is reduced to around 10⁻⁵ mbar and the heater 314 is activated to raise the temperature of the sapphire counter surface 310 sufficiently for radiated heat to raise the temperature of the copper substrate 302 to around 1080° C., close to the melting point of copper. As the substrate support member 308 is distal from the sapphire counter surface 310 and its source of radiated heat, its temperature is correspondingly lower than that of the copper substrate 302, the temperature of the elements within the vacuum chamber increasing in the direction C.

The temperature of the copper substrate 302 is thus sufficient for the evaporation of copper from its evaporation surface 304 to form a copper gas in an interstitial region 311 between the copper substrate 302 and the substrate support member 308. As the substrate support member 308 is cooler than the evaporation surface 304 of the copper substrate 302, the copper gas 309 preferentially condenses onto the substrate support surface 307 of the substrate support member 308, producing a thin and uniform film of copper thereon.

In a subsequent step, the copper substrate 302 and the spacers 306 positioned between the copper substrate 302 and the substrate support member 308 are removed to provide an arrangement 301 as shown in FIG. 3B.

In this arrangement 301, a copper film 313, having been formed on the substrate support surface 307 and of the substrate support member 308, is separated by the spacers 312 from the sapphire counter surface 310, maintaining a distance of 250 μm between the counter surface 310 and a growth surface 315 of the copper film 313 on which it is intended to grow a graphene layer.

In use, the pressure in the ultra high vacuum chamber 316 is reduced to less than around 10⁻⁵ mbar and the sapphire counter surface 310 is slowly heated to around 1140° C. This in turn heats the copper film 313 by radiated heat to around 1040° C. Hydrogen (at a partial pressure of about 7×10⁻⁵ mbar) is added to anneal the copper film 313 during the heating. The arrangement 301 is held at the high temperature for 2 hours.

Where copper evaporates from the growth surface 315 to produce gaseous copper 318, that gaseous copper 318 is restricted in its movement to the volume within the small interstitial space 320 between the growth surface 315 and the counter surface 310. This effect is enhanced where the spacers 312 also fully or partially prevent escape of gaseous copper from the interstitial space 320.

Moreover, as the counter surface 310 is held at a higher temperature than the copper film 313, the gaseous copper 318 does not condense and/or form a copper film on the counter surface 310. The effect is that the gaseous copper 318 is likely only to condense on the growth surface 315, in turn providing a copper atom flux at the growth surface 315 of zero or near zero and ensuring that the surface is substantially flat over its entire area.

While the temperature of the counter surface 310 and the copper film 313 is maintained, a ethylene gas 322 is introduced to the interstitial space 320 between the growth surface and the counter surface 310 at a partial pressure of 5×10⁻⁴ mbar. Hydrogen gas is also present at a partial pressure of 4×10⁻⁴ mbar. A graphene layer having a highly uniform nucleation density is thus formed on the growth surface 315.

### Example 3

A 1 cm² graphene layer was produced according to the method described in relation to FIG. 3, above. An SEM photograph (200× magnification) showing graphene formed on the growth surface 315 is shown in FIG. 3C. A second SEM photograph (3000× magnification) is shown in FIG. 3D.

As can be seen, the graphene layer is extremely highly uniform in its topography, the layer shows a low and uniform nucleation density and large grain sizes are observed. It is postulated that this is because the nucleation density of graphene formed on copper is generally influenced by local contamination and the crystal orientation of the copper. In this instance, the purity of the copper film negates these effects, apparently making the graphene growth parameters (e.g. the local pressures) the primary drivers of nucleation density.

### Example 4A

In this Example, the method described in relation to FIG. 3 was generally followed, however the copper foil used as a source for the deposition of the copper layer was retained during ethylene exposure to act as the counter surface thereby to provide a positive copper flux at the growth surface.

The copper foil was heated to 1050° C. to provide a temperature of 1000° C. at the growth surface during a 2 hour annealing in hydrogen at less than 10⁻⁵ mbar. The temperature was maintained during exposure to ethylene at a partial pressure of 5×10⁻⁴ mbar and hydrogen at 5×10⁻⁴ mbar, lasting for 35 minutes.

An SEM photograph (800× magnification) of the graphene layer produced is shown in FIG. 4A. As can be seen, the graphene grains are large, having grown to a size of approximately 400 μm.

### Example 4B

In this Example, the method of Example 4A was generally followed.

The copper foil was heated to 1040° C. to provide a temperature of 960° C. at the growth surface during a 2 hour annealing in hydrogen at less than 10⁻⁵ mbar. The temperature was maintained during exposure to ethylene at a partial pressure of 1.8×10⁻³ mbar and hydrogen at 2×10⁻⁴ mbar, the hydrogen pressure slowly increasing over the 33 minute exposure period.

An SEM photograph (400× magnification) of the graphene layer produced is shown in FIG. 4A. As can be seen, the graphene grains are large and have a uniform alignment, allowing for the growth of large grains and minimising grain boundary effects.

### Comparative Example 1

A 1 cm² graphene film was formed on a copper foil by annealing a copper foil at a temperature of 980° C. in hydrogen in an ultra-high vacuum chamber at a pressure of less than 10⁻⁵ mbar, before exposing the copper foil to ethylene gas at a partial pressure of 1.8×10⁻³ mbar and hydrogen at a partial pressure of 2×10⁻⁴ mbar. The substrate was exposed to the ethylene gas for 25 mins to form a graphene film on the surface of the foil.

In the absence of a means for restricting the dissipation of the gaseous copper formed from the copper foil, a negative net copper flux at the surface of the foil was observed. An SEM photograph showing the graphene layer on the copper foil can be seen in FIG. 5A and 5B. It is clear that the surface of the graphene film is rough and that relatively small and inconsistent regions of graphene are formed on copper mountains on the surface of the foil. It is postulated that this is because (i) graphene grows on a rough copper surface resulting from the negative net copper flux; and (ii) at growth conditions for graphene and during growth of graphene, the formation of graphene on the copper surface roughens the copper surface, since no copper can evaporate from underneath the graphene in areas of the copper surface covered by graphene, and there is still a negative net copper flux in areas of the copper surface not covered by graphene.

An arrangement 400 for performing a method in accordance with an embodiment of the invention is shown in FIG. 6.

The arrangement 400 includes a copper substrate 402 having a growth surface 404 on which it is intended to grow a layer of graphene.

Facing the growth surface 404 of the copper substrate 402 and in a substantially parallel plane thereto is positioned a copper counter surface 410. Spacers 412 are provided between the copper counter surface 410 and the growth surface 404 of the copper substrate 402 in order to maintain a distance therebetween.

A heater 414 is provided in intimate contact with the copper counter surface 410. Another heater 424 is provided in intimate contact with the copper substrate 402. The entire arrangement 400 is held within an ultra high vacuum chamber 416.

The provision of the two heaters 414,424 improves control over the temperatures of both the copper counter surface 410 and the copper substrate 402.

In use, the heaters 414,424 may be controlled to provide a temperature differential between the copper counter surface 410 and the copper substrate 402 such that the copper counter surface 410 is held at a higher or lower temperature than the copper substrate 402 so as to control the copper atom flux at the copper counter surface 410 and growth surface 404.

In use, the pressure in the ultra high vacuum chamber 416 is reduced to less than around 1×10⁻⁵ mbar, and the copper counter surface 410 is slowly heated to a temperature in the range of 800° C. to 1000° C. Meanwhile the heaters 414,424 are controlled to provide a temperature differential between the copper counter surface 410 and the copper substrate 402 such that the copper counter surface 410 is held at a higher or lower temperature than the copper substrate 402. Hydrogen (at a partial pressure of about 7×10⁻⁵ mbar) is added to clean and/or anneal the copper substrate 402 during the heating. The arrangement 400 is held at the high temperature for 2 hours.

Where copper evaporates from the growth surface 404 and the copper counter surface to produce gaseous copper 418, that gaseous copper 418 is restricted in its movement to the volume within the small interstitial space 420 between the growth surface 404 and the counter surface 410. This effect is enhanced where the spacers 412 also fully or partially prevent escape of gaseous copper from the interstitial space 420.

Moreover, as the copper counter surface 410 is held at a different temperature than the copper substrate 402, the gaseous copper 418 produced from the copper counter surface 410 and the growth surface 404 preferentially condenses on either the growth surface 404 or the counter surface 410, in turn providing a positive copper atom flux at either the growth surface 404 or the counter surface 410, depending on whether the copper counter surface 410 is held at a higher or lower temperature than the copper substrate 402.

While the temperatures of the counter surface 410 and the copper substrate 402 are maintained by the heaters to provide a temperature differential between the copper counter surface 410 and the copper substrate 402, a carbon containing precursor gas 422 is introduced to the interstitial space 420 between the growth surface 404 and the copper counter surface 410 at a partial pressure of 2×10⁻³ mbar. Hydrogen gas is also present at a partial pressure of 6×10⁻⁴ mbar. A layer of graphene is thus formed on the growth surface 404.

If desired, the heaters may be controlled to reverse the temperature differential between the copper counter surface 410 and the copper substrate 402.

Alternatively, in use, the heaters 414,424 may be controlled so that the temperature of the copper counter surface 410 is substantially equal to the temperature of the copper substrate 402 (preferably so that the temperature of the copper counter surface 410 is exactly equal to the temperature of the copper substrate 402, i.e. there is a zero temperature differential between the temperatures of the copper counter surface 410 and the copper substrate 402).

In use, the pressure in the ultra high vacuum chamber 416 is reduced to less than around 1×10⁻⁵ mbar, and the counter surface and copper substrate 410,402 are slowly heated to the same temperature of 800° C. to 1000° C. Hydrogen (at a partial pressure of about 7×10⁻⁵ mbar) is added to clean and/or anneal the copper substrate 402 during the heating. The arrangement 400 is held at the high temperature for 2 hours.

Where copper evaporates from the growth surface 404 and the copper counter surface to produce gaseous copper 418, that gaseous copper 218 is restricted in its movement to the volume within the small interstitial space 420 between the growth surface 404 and the counter surface 410. This effect is enhanced where the spacers 412 also fully or partially prevent escape of gaseous copper from the interstitial space 420.

Moreover, as the copper counter surface 410 and copper substrate 402 are held at substantially equal temperatures, the net copper atom flux at each of the copper counter surface 410 and growth surface 404 is minimal, thus ensuring that the growth surface 404 is substantially flat over its entire area.

While the temperatures of the counter surface 410 and the copper substrate 402 are maintained by the heaters 414,424 so that the temperature of the copper counter surface 410 is substantially equal to the temperature of the copper substrate 402, a carbon containing precursor gas 422 is introduced to the interstitial space 420 between the growth surface 404 and the counter surface 410 at a partial pressure of 2×10⁻³ mbar. Hydrogen gas is also present at a partial pressure of 6×10⁻⁴ mbar. A layer of graphene is thus formed on the growth surface 404.

It is envisaged that, prior to heating the counter surface and copper substrate 410,402 to substantially the same temperature, the copper substrate 402 may be annealed at a high temperature in hydrogen in an ultra-high vacuum chamber at a reduced pressure and in the absence of the copper counter surface 410, so as to provide a negative net copper flux at the growth surface 404 and thereby create a rough growth surface 404 that is similar to that seen in FIGS. 5A and 5B. Formation of the layer of graphene at a near-zero or zero temperature differential between the counter surface 410 and the copper substrate 402, as described above, results in formation of a layer of graphene on the rough growth surface 404.

It will be appreciated that formation of a layer of graphene on a rough growth surface 404 may also be carried out by applying a non-zero temperature differential between the counter surface 410 and the copper substrate 402, and by growing graphene on the growth surface 404 of the copper substrate 402 when there is a non-zero temperature differential between the counter surface 410 and the copper substrate 402. This is because, at growth conditions for graphene and during growth of graphene, the formation of graphene on the growth surface 404 roughens the growth surface 404, since:
if the temperature of the counter surface 410 is lower than the temperature of the copper substrate 402, no copper can evaporate from underneath the graphene in areas of the growth surface 404 covered by graphene, and there is still a negative net copper flux in areas of the growth surface 404 not covered by graphene, or
if the temperature of the counter surface 410 is higher than the temperature of the copper substrate 402, copper arriving from the counter surface 410 cannot be deposited on areas of the growth surface 404 covered by graphene, but can be deposited on areas of the growth surface 404 not covered by graphene. This results in non-uniform deposition of copper and hence a roughening of the growth surface 404.

An arrangement 500 for performing a method in accordance with an embodiment of the invention is shown in FIGS. 7A and 7B.

The arrangement 500 shown in FIG. 7A includes a copper counter surface 510 from which it is intended to evaporate copper. The copper counter surface 510 is mounted by way of spacers 506 on a sapphire substrate support member 508 such that the copper counter surface 510 is opposed to a substrate support surface 507 of the substrate support member 508. The copper counter surface 510 is further mounted directly on a sapphire substrate 513.

A heater 514 is provided in intimate contact with the sapphire substrate 513 on which the copper counter surface 510 is directly mounted. Another heater 524 is provided in intimate contact with the sapphire substrate support member 508. The entire arrangement 500 is held within an ultra high vacuum chamber 516.

Initially, the pressure in the high vacuum chamber is reduced to around 10⁻⁴ mbar (with hydrogen being present) and the heaters 514,524 are controlled so that the temperature of the copper counter surface is at 1000° C. and the temperature of the substrate support member 508 is at 870° C.

The temperature of the copper counter surface 510 is thus sufficient for the evaporation of copper from the copper counter surface 510 to form a copper gas in an interstitial region 511 between the copper counter surface 510 and the substrate support member 508. As the substrate support member 508 is cooler than the evaporation surface 504 of the copper counter surface 510, the copper gas 509 preferentially condenses onto the substrate support surface 507 of the substrate support member 508, producing a thin and uniform film of copper thereon.

In a subsequent step, the copper counter surface 510 and the spacers 506 positioned between the copper counter surface 510 and the substrate support member 508 are rearranged to provide an arrangement 501 as shown in FIG. 7B.

In this arrangement 501, a copper film 515 (which defines a copper substrate), having been formed on the substrate support surface 507 of the substrate support member 508, is separated by the spacers 506 from the sapphire counter surface 510, maintaining a distance between the copper counter surface 510 and a growth surface 504 of the copper film 515 on which it is intended to grow a graphene layer.

In use, the pressure in the ultra high vacuum chamber 516 is reduced to less than around 10⁻⁵ mbar, the copper counter surface 510 is slowly heated to 1040° C. and the substrate support member 508 (and therefore the copper film 515) is slowly heated to 977° C., i.e. a temperature that is substantially equal to the temperature of the copper counter surface 510 of 1040° C.. It is envisaged that the copper counter surface 510 and substrate support member 508 may instead be heated to exactly the same temperature so that there is a zero temperature differential between the temperatures of the copper counter surface 510 and substrate support member 508.

Hydrogen (at a partial pressure of about 7×10⁻⁵ mbar) is added to anneal the copper film 515 during the heating. The arrangement 501 is held at the high temperature for 2 hours.

Where copper evaporates from the growth surface 504 to produce gaseous copper 518, that gaseous copper 518 is restricted in its movement to the volume within the small interstitial space 520 between the growth surface 504 and the counter surface 510. This effect is enhanced where the spacers 506 also fully or partially prevent escape of gaseous copper from the interstitial space 520.

Moreover, as the copper counter surface 510 and the substrate support member 508 are held at substantially equal temperatures, the net copper atom flux at each of the copper counter surface 510 and growth surface 504 is minimal, thus ensuring that the growth surface 504 is substantially flat over its entire area.

While the temperatures of the counter surface 510 and the substrate support member 508 are maintained by the heaters 514,524 so that the temperature of the copper counter surface 510 is substantially equal to the temperature of the copper film 515, a carbon containing precursor gas 522 is introduced to the interstitial space 520 between the growth surface 504 and the counter surface 510 at a partial pressure of 5×10⁻⁴ mbar. Hydrogen gas is also present at a partial pressure of 4×10⁻⁴ mbar. A graphene layer having a highly uniform nucleation density is thus formed on the growth surface 504.

During cooling down of the substrate support member 508 and copper film 515, the temperatures of the counter surface 510 and the copper film 515 are maintained to be substantially equal so as to prevent copper deposition on the growth surface 504 and the graphene layer.

FIGS. 8A and 8B respectively show AFM and SEM photographs of the graphene layer produced in accordance with the method described above with regard to FIGS. 7A and 7B. As can be seen from FIG. 8A, the height scale of the AFM photograph is 12.2 nm, which indicates a high level of smoothness of the graphene layer, while, as can be seen from FIG. 8B, the copper film 515 is mostly covered by graphene. In FIG. 8, the white parts indicate areas that are not covered by graphene.

No doubt many other effective alternatives will occur to the skilled person. It will be understood that the invention is not limited to the described embodiments and encompasses modifications apparent to those skilled in the art lying within the spirit and scope of the invention. For example, the skilled person will appreciate that while it is preferred that where the temperature of the counter surface is higher than that of the metal substrate, that temperature difference is around 100° C., the method will be effective if the temperature difference is higher or lower than that figure. In particular the skilled person will appreciate that providing the temperature of the counter surface is higher than that of the metal substrate, gaseous metal will preferentially condense onto the metal substrate. Moreover, the only upper limit on the temperature of the counter surface in this instance is provided by the potential for overheating the metal substrate by radiated heat.

Furthermore, the skilled person understands that other means than spacers may be used to maintain the separation of the substrates, supports and counter surfaces in use. For example, one, some or all of those elements may be mounted on robotic arms such that the spacings may be easily adjusted in real time. It will be appreciated that at small spacings (for example less than about 1 mm) between a substrate and its counter surface, there is no need to provide any barrier to gas flow at the periphery of the substrate.

It is also understood that methods of the present invention could be utilised for the growth of a plurality of layers of graphene.

1. A method for forming a graphene film on one or more surfaces of a metal substrate, the method comprising the steps of:
(i) heating a metal substrate defining one or more surfaces to an exposure temperature;
(ii) restricting the metal flux from the one or more surfaces at the exposure temperature by provision of one or more counter surfaces proximal to one or more of the surfaces of the substrate;
(iii) exposing the substrate to a carbon containing precursor gas at the exposure temperature so as to form a graphene film on the or each surface of the substrate.

2. (canceled)

3. A method according to claim 1, wherein the temperature of the one or more counter surfaces is controlled to provide a temperature differential between the substrate and the counter surface.

4. A method according to claim 3, under one or more of the following conditions:
(a) wherein the one or more counter surfaces are held at a higher or lower temperature than the substrate;
b) wherein the one or more counter surfaces are held at a temperature of up to 500° C. higher than the exposure temperature of the metal substrate;
c) wherein the one or more counter surfaces are held at a temperature of up to 400° C. higher than the exposure temperature of the metal substrate;
(d) wherein the one or more counter surfaces are held at a temperature of up to 300° C. higher than the exposure temperature of the metal substrate;
e) wherein the one or more counter surfaces are held at a temperature of up to 200° C. higher than the exposure temperature of the metal substrate; and
f) wherein the one or more counter surfaces are held at a temperature of up to 100° C. higher than the exposure temperature of the metal substrate.

5-11. (canceled)

12. A method according to claim 1, wherein the one or more counter surfaces comprise a material different to the metal substrate.

13. A method according to claim 12 under one or more of the following conditions:
(a) wherein the one or more counter surfaces comprise a material having at least one of a higher vapour pressure, boiling point, and sublimation point than the metal substrate;
b) wherein the one or more counter surfaces comprise a material having at least one of a higher vapour pressure boiling point and sublimation point than the metal substrate, and the one or more counter surfaces comprises molybdenum;
(c) wherein the one or more counter surfaces comprise a material having at least one of a higher vapour pressure, boiling point, and sublimation point than the metal substrate, and the one or more counter surfaces comprise a ceramic or mineral material.

14-27. (canceled)

28. A method according to claim 1, wherein the metal substrate is supported on a substrate support member.

29. A method according to claim 28 under one or more of the following conditions:
(a) wherein the substrate support member comprises a material having at least one of a higher vapour pressure, boiling point, and sublimation point than the metal substrate;
(b) wherein the substrate support member comprises a material having at least one of a higher vapour pressure, boiling point, and sublimation point than the metal substrate and the substrate support member comprises molybdenum;
(c) wherein the substrate support member comprises a material having at least one of a higher vapour pressure, boiling point, and sublimation point than the metal substrate, and the substrate support member comprises a ceramic or mineral material;
(d) wherein the metal substrate is as least partially spaced from the substrate support member;
(e) wherein the metal substrate is at least partially spaced from the substrate support member by the provision of one or more spacers.

30-32. (canceled)

33. A method according to claim 28, further comprising preliminary steps of:
(a) disposing the or a substrate support member having a substrate support surface adjacent to a metal substrate precursor;
(b) heating the metal substrate precursor to an evaporation temperature at reduced pressure so as to deposit a metal substrate layer on the substrate support surface.

34. A method according to claim 33, wherein the substrate support surface is held at a lower temperature than the evaporation temperature of the metal substrate precursor during the deposition of metal thereon.

35. A method according to claim 1 including one or more of:
(a) the step of providing a heater source in intimate contact with the one or more counter surfaces; and
(b) the preliminary step of heating the metal substrate to an evaporation temperature at reduced pressure so as to create a negative or positive net metal flux at the one or more surfaces of the metal substrate.

36. (canceled)

37. An arrangement for forming a graphene film on one or more surfaces of a metal substrate, the arrangement comprising:
a. a metal substrate defining one or more surfaces;
b. a heat source to heat the metal substrate to an exposure temperature;
c. one or more counter surfaces provided proximal to one or more of the surfaces of the substrate to restrict the metal flux from the one or more surfaces at the exposure temperature;
d. a carbon containing precursor gas source to expose the substrate to a carbon containing precursor gas at the exposure temperature so as to form a graphene film on the or each surface of the substrate.

38. (canceled)

39. An arrangement according to claim 37 wherein the temperature of the one or more counter surfaces is controlled to provide a temperature differential between the substrate and the counter surface.

40. An arrangement according to claim 39, under one of more of the following conditions:
(a) wherein the one or more counter surfaces are held at a higher or lower temperature than the substrate;
b) wherein the one or more counter surfaces are held at a temperature of up to 500°C. higher than the exposure temperature of the metal substrate;
c) wherein the one or more counter surfaces are held at a temperature of up to 400°C. higher than the exposure temperature of the metal substrate;
(d) wherein the one or more counter surfaces are held at a temperature of up to 300° C. higher than the exposure temperature of the metal substrate;
e) wherein the one or more counter surfaces are held at a temperature of up to 200° C. higher than the exposure temperature of the metal substrate; and
f) wherein the one or more counter surfaces are held at a temperature of up to 100° C. higher than the exposure temperature of the metal substrate.

41-44. (canceled)

45. An arrangement according to claim 37, wherein the one or more counter surfaces are arranged to be heated by direct contact with or by radiated heat from the heat source, and either:
the metal substrate is arranged to be at least partially heated to the exposure temperature by radiated heat from the one or more counter surfaces, or
the arrangement includes another heat source, wherein the metal substrate is arranged to be at least partially heated to the exposure temperature by the direct contact with or by radiated heat from another heat source.

46-47. (canceled)

48. An arrangement according to claim 37, wherein the one or more counter surfaces comprise a material different to the metal substrate.

49. An arrangement according to claim 48, under one or more of the following conditions:
a) wherein the one or more counter surfaces comprise a material having a at least one of higher vapour pressure boiling point, and sublimation point than the metal substrate;
b) wherein the one or more counter surfaces comprise a material having at least one of a higher vapour pressure, boiling point, and sublimation point than the metal substrate, and the one or more counter surfaces comprises molybdenum; and
(c) wherein the one or more counter surfaces comprise a material having at least one of a higher vapour pressure, boiling point, and sublimation point than the metal substrate, and the one or more counter surfaces comprise a ceramic or mineral material.

50-63. (canceled)

64. An arrangement according to claim 37, wherein the metal substrate is supported on a substrate support member.

65. An arrangement according to claim 64, under one or more of the following conditions;
(a) wherein the substrate support member comprises a material having at least one of a higher vapour pressure, boiling point, and sublimation point than the metal substrate;
(b) wherein the substrate support member comprises a material having at least one of a higher vapour pressure, boiling point, and sublimation point than the metal substrate, and the substrate support member comprises molybdenum;
(c) wherein the substrate support member comprises a material having at least one of a higher vapour pressure, boiling point, and sublimation point than the metal substrate, and the substrate support member comprises a ceramic or mineral material;
(d) wherein the metal substrate is as least partially spaced from the substrate support member;
(e) wherein the metal substrate is at least partially spaced from the substrate support member by the provision of one or more spacers.

66-68. (canceled)

69. An arrangement according to claim 64 including:
a. a metal substrate precursor, the or a substrate support member having a substrate support surface being disposed adjacent to the metal substrate precursor;
b. a heat source;
c. a pressure controller to create a reduced pressure;
wherein the heat source and pressure controller are configured to enable heating of the metal substrate precursor to an evaporation temperature at reduced pressure so as to deposit a metal substrate layer on the substrate support surface.

70. An arrangement according to claim 69, wherein the substrate support surface is held at a lower temperature than the evaporation temperature of the metal substrate precursor during the deposition of metal thereon.

71. An arrangement according to claim 37 under one or more of the following conditions:
(a) wherein the heater source is provided in intimate contact with the one or more counter surfaces; and
b) wherein the arrangement includes a pressure controller to create a reduced pressure, wherein the heat source and pressure controller are configured to enable heating of the metal substrate to an evaporation temperature at reduced pressure so as to create a negative or positive net metal flux at the one or more surfaces of the metal substrate.

72-73. (canceled)
